(19) United States
(12) Patent Application Publication
(10) Pub. No.: US 2009/0189618 A1
(43) Pub. Date: Jul. 30, 2009

(54) METHOD, SYSTEM, AND APPARATUS FOR LIQUID MONITORING, ANALYSIS, AND IDENTIFICATION

(76) Inventor: Michael F. Hoey, Shoreview, MN (US)

Correspondence Address: Richman and Associates, PO Box 3333, La Jolla, CA, 92038-3333, US

(21) Appl. No.: 12/019,626

(22) Filed: Jan. 24, 2008

(51) Int. Cl. G01R 27/26; G01N 27/06

(52) U.S. Cl. 324/663

(57) ABSTRACT

Embodiments of liquid monitoring, analysis, and identification are described generally herein. Other embodiments may be described and claimed.

### TECHNICAL FIELD

Various embodiments described herein relate generally to liquid monitoring, analysis, and identification, including architecture, systems, and methods used in liquid monitoring, analysis, and identification.

### BACKGROUND INFORMATION

It may be desirable to monitor, analyze, or identify liquid via one or more devices or probes. A user may employ a device or probes to control or limit the flow of liquid, provide medical diagnosis or identification of cell(s) within the liquid.

### BRIEF DESCRIPTION OF THE DRAWINGS

FIGS. 1A-1D are simplified diagrams of a liquid probe system according to various embodiments.

FIG. 2A is a partial diagram of a probe tip including several optical modules or groups according to various embodiments.

FIG. 2B is an isometric diagram of a probe system including several optical modules or groups according to various embodiments.

FIG. 3 is a diagram of an optical probe system including a probe tip and optical modulator according to various embodiments.

FIGS. 4A-4D are simplified diagrams of employed liquid probe systems according to various embodiments.

FIGS. 5A-5D are simplified diagrams of employed liquid probe systems according to various embodiments.

FIG. 6A is simplified diagrams of a flow control system with a liquid probe system according to various embodiments.

FIG. 6B is simplified diagrams of another flow control system with a liquid probe systems according to various embodiments.

FIG. 7A-8 are diagrams of signals that may be applied to one or more liquid probe modules or groups according to various embodiments.

FIGS. 9A-9B are flow diagrams illustrating a liquid probe system processing algorithm according to various embodiments.

FIG. 10 is a block diagram of an article according to various embodiments.

### DETAILED DESCRIPTION

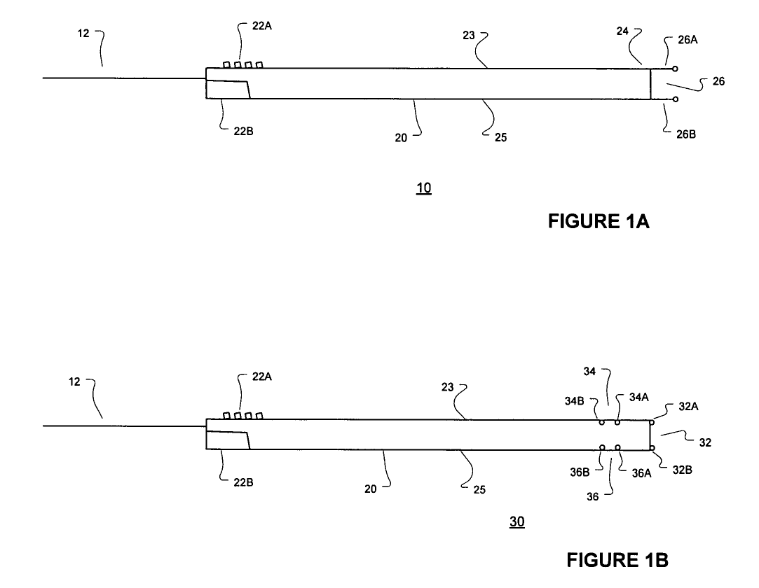

FIG. 1A is a simplified diagram of a liquid probe system 10 according to various embodiments. The liquid probe system 10 may include an elongated probe 20. The elongated probe 20 includes a tip 24, a top section 23, and a bottom section 25. The probe system 10 may include at least one bipolar module 26 including a first electrode 26A and a second electrode 26B. The first bipolar module 26 may be located on the distal tip 24. In an embodiment the first bipolar module 26 may be energized to determine characteristics of liquid located near or adjacent to the tip 24. The electrodes 26A, 26B may be an electrode pair where one is an anode and the other the cathode of the electrode pair. One or more conductive wires 12 may be coupled to the electrodes 26A, 26B.

In an embodiment a bipolar module 26 may be energized with electrical signal(s) via the conductive wires 12. The invention may monitor the electrical signal(s) as applied to the module 26. For an electrical signal the invention may monitor the characteristics of the electrical signal and determine characteristics of liquid that is near or adjacent the module 26 as a function of the monitored electrical signal characteristics. The electrical signal characteristics may include amplitude, phase, impedance, capacitance, and inductance over time or frequency.

In an embodiment the liquid probe system 10 may include one or more user detectable signal generation units 22A, 22B. The detectable signal generation unit 22A may include one or more light emitting diodes (LEDs). One or more LEDs may be energized as a function of signals generated by, received by, or generated in response to the energized bipolar module 26 as discussed above. The LEDs 22A may generate a different frequency or intensity of light as a function of signals generated by, received by, or generated in response to the energized bipolar module 26. The detectable signal generation unit 22B may create a tactilely detectable signal including a vibration that a user manipulating the probe 20 may feel. The vibration intensity may vary as a function of signals generated by, received by, or generated in response to the energized bipolar module 26. In an embodiment the probe 20 may be curved and flexible.

FIG. 1B is a simplified diagram of another liquid probe system 30 according to various embodiments. The liquid probe system 30 may include the elongated probe 20 with a tip 24, a top section 23, and a bottom section 25. The probe system 30 may include at least three bipolar modules 32, 34, 36 each including at least two electrodes. A bipolar module 32 may be located on the distal tip 24, a bipolar module 34 may be located on a top section 23, and a bipolar module 36 may be located on a bottom section 36. In an embodiment one or more bipolar modules 32, 34, 36 may be energized, simultaneously or alternatively to determine characteristics of liquid located near or adjacent to the tip 24, top section 23, or bottom section 25.

The electrodes 32A, 32B may be an electrode pair where one is an anode and the other the cathode of the electrode pair. One or more conductive wires 12 may be coupled to the electrodes 32A, 32B. The electrodes 34A, 34B may also be an electrode pair where one is an anode and the other the cathode of the electrode pair. One or more conductive wires 12 may be coupled to the electrodes 34A, 34B. The electrodes 36A, 36B may also be an electrode pair where one is an anode and the other the cathode of the electrode pair. One or more conductive wires 12 may be coupled to the electrodes 36A, 36B. In an embodiment each electrode 32A, 32B, 34A, 34B, 36A, 36B may be independently coupled to a conductive wire 12. In another embodiment one or electrodes 32A, 32B, 34A, 34B, 36A, 36B may be commonly coupled to a conductive wire 12. In an embodiment, 32A, 34A, and 36A may be commonly coupled to a conductive wire 12 and 32B, 34B, and 36B may be commonly coupled to another conductive wire 12.

In an embodiment a bipolar module 32 and one or more the bipolar modules 34, 36 may be simultaneously energized with electrical signal(s) via the conductive wires 12. In an embodiment a single bipolar module 32, 34, 36 may be separately energized with an electrical signal(s) via the conductive wires 12. The invention may monitor the electrical signal(s) as applied to the modules 32, 34, 36. The invention may monitor the characteristics of the electrical signal(s) and determine characteristics of liquid that is near or adjacent the modules 32, 34, 36 as a function of the monitored electrical signal characteristics. The electrical signal characteristics may include amplitude, phase, impedance, capacitance, and inductance over time or frequency.

In the probe system 30 one or more LEDs 22A may be energized as a function of signals generated by, received by, or generated in response to the energized bipolar modules 32, 34, 36 as discussed above. The LEDs 22A may generate different frequency or intensity of light as a function of signals generated by, received by, or generated in response to the energized bipolar modules 32, 34, 36. In an embodiment one or more LEDs 22A may correspond to a particular bipolar module 32, 34, 36. The detectable signal generation unit 22B may create a tactilely detectable signal including a vibration that a user manipulating the probe system 30 may feel. The vibration intensity may vary as a function of signals generated by, received by, or generated in response to energized bipolar modules 32, 34, 36.

FIG. 1C is a simplified diagram of a liquid probe system 40 according to various embodiments. The liquid probe system 40 may include at least two elongated probes 42A, 42B. Each elongated probe 42A, 42B may include an electrode 44A, 44B. In an embodiment the electrodes 44A, 44B may be located on the distal tip of the probe 42A, 42B. In an embodiment the electrodes 44A, 44B form a first bipolar module 44 that may be energized to determine characteristics of liquid located near or adjacent to the electrodes 44A, 44B. The electrodes 44A, 44B may be an electrode pair where one is an anode and the other the cathode of the electrode pair. A conductive wire 46A may be coupled to the electrode 44A and a conductive wire 46B may be coupled to the electrode 44B.

In an embodiment the bipolar module 44 may be energized with electrical signal(s) via the conductive wires 46A, 46B. The invention may monitor the electrical signal(s) as applied to the module 44. The invention may monitor the characteristics of the electrical signal and determine characteristics of liquid that is near or adjacent the electrodes 44A, 44B as a function of the monitored electrical signal characteristics. The electrical signal characteristics may include amplitude, phase, impedance, capacitance, and inductance over time or frequency.

FIG. 1D is a simplified diagram of a liquid probe system 50 according to various embodiments. The liquid probe system 50 may include an elongated, cannulated probe 52. The elongated probe 52 includes an outer surface 58A and an inner surface 58B. The probe system 50 may include at least one bipolar module 54 including a first electrode 54A and a second electrode 54B. The bipolar module 54 may be located on the outer surface 58A and electrically coupled to the probe 52 inner surface 58B. In an embodiment the bipolar module 54 may be energized to determine characteristics of liquid located within the probe 52 cannulation. The electrodes 54A, 54B may be an electrode pair where one is an anode and the other the cathode of the electrode pair. A conductive wire 56A may be coupled to the electrode 54A and a conductive wire 56B may be coupled to the electrode 56A.

In an embodiment the bipolar module 54 may be energized with electrical signal(s) via the conductive wires 56A, 56B. The invention may monitor the electrical signal(s) as applied to the module 54. The invention may monitor the characteristics of the electrical signal and determine characteristics of liquid that is near or adjacent the module 54 via the probe 52 inner surface 58B as a function of the monitored electrical signal characteristics. The electrical signal characteristics may include amplitude, phase, impedance, capacitance, and inductance over time or frequency.

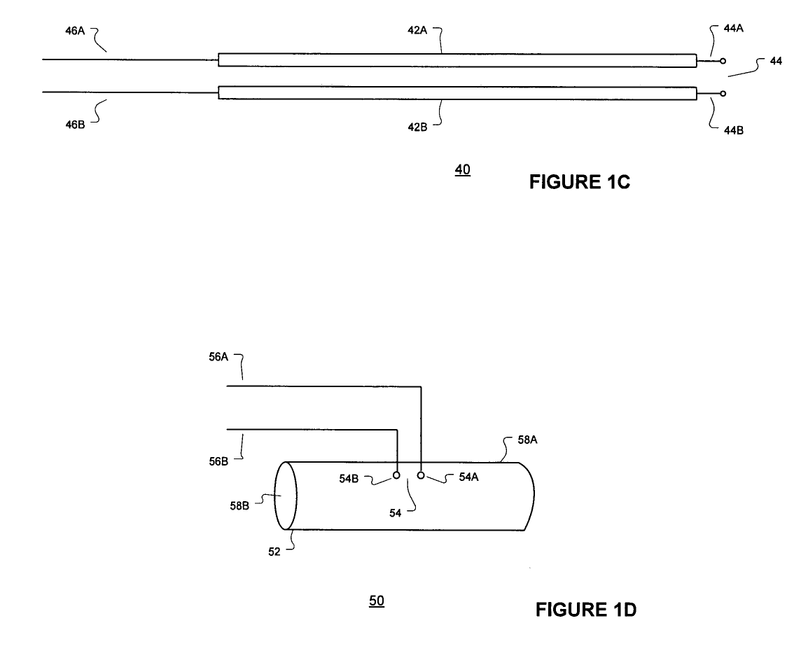

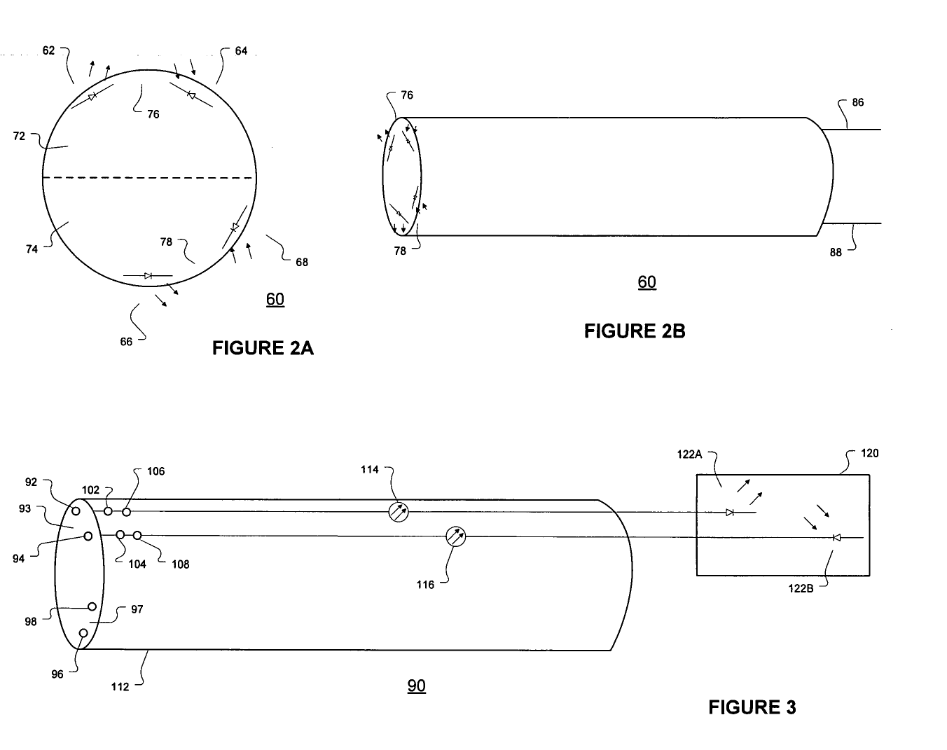

For each of the probe systems 10, 30, 40, 50 liquid may be relatively stationary (static) relative to the electrode module(s) or may flow pass one or more electrode modules. In an embodiment, the liquid(s) to be characterized may include biological fluids. FIG. 2A is a top diagram of a probe tip a liquid probe system 60 including several optical modules or groups 76, 78 according to various embodiments. FIG. 2B is a partial isometric diagram of the liquid probe system 60 including several optical modules or groups 76, 78 according to various embodiments. Each optical module or group 76, 78 may include a light emitting device 62, 66 and light detecting device 64, 68.

In an embodiment the light emitting device 62, 66 is an LED and the light detecting device 64, 68 is a semiconductor based light detecting diode (LDD). In operation a LED 62 of an optical module 76 of the section 72 may be energized with a first signal via one or more conductive wires 86 for a predetermined time interval to generate an optical signal that may be partially reflected or absorbed as a function of the liquid illuminated by the optical signal. The LED 62 may be configured to generate photons having one or more predetermined frequencies where the one or more predetermined frequencies are a function of the optimal absorption or reflectance of the targeted liquid. The LDD 64 of the optical module 76 may detect an optical signal reflected from a liquid. The optically detected signal may provide an indication of the identity, density, flow rate, concentration, temperature, or other measurable property of a liquid as a function of the difference of the optical signal generated by the LED 62 and detected by the LDD 64.

Similarly a second electrical signal may be applied to the LED 66 of the optical module 78 of the section 74 via one or more conductive wires 88 for a second predetermined time interval where the LED 66 may be configured to generate photons having one or more predetermined frequencies where the one or more predetermined frequencies are a function of the optimal absorption or reflectance of the targeted liquid. The LDD 68 of the optical module 78 may detect optical energy reflected from a liquid. The second optically detected signal may provide an indication of the identity, density, flow rate, concentration, temperature, or other measurable property of a liquid as a function of the difference of the optical signal generated by the LED 66 and detected by the LDD 68.

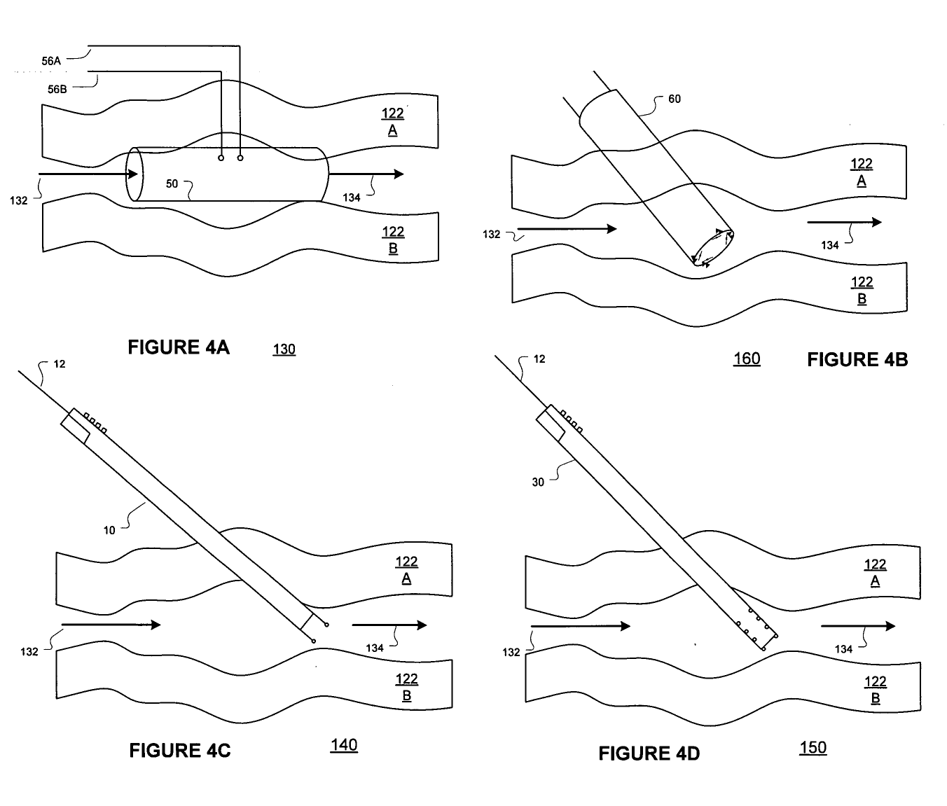

FIG. 3 is a side diagram of an optically based liquid probe system 90 including a probe distal section 112 and an optical modulator 120 according to various embodiments. In the optical system 90 an optical module 93 may include a LED lens 92, a LDD lens 94, a fiber optic pathway 114, a fiber optic pathway 116, a LED 122, and a LDD 124. In this embodiment the LED 122 may be coupled to a lens 92 via the fiber optic pathway 114. The LDD 124 may be coupled the lens 94 via the fiber optic pathway 1 16. Similarly, the LED 122 may be coupled to the lens 96 via a fiber optic pathway and the LDD 124 may be coupled the lens 98 via a fiber optic pathway. Further a lens 102 and 106 may be coupled to the LED 122 via the pathway 114. A lens 104 and 108 may be coupled to the LDD 124 via the pathway 116.

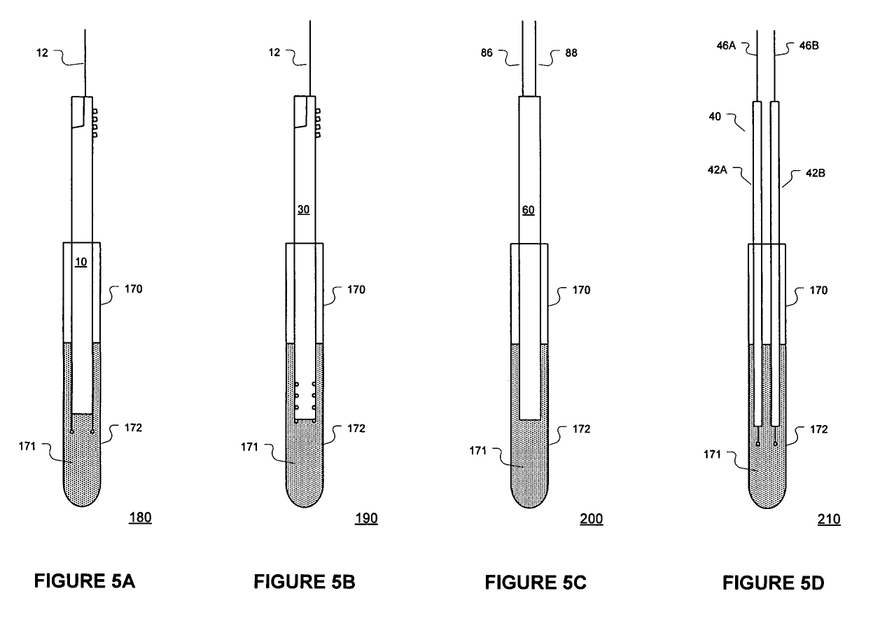

The LED 122 and LDD 124 may be located remote to the probe distal end 112 in an optical modulator 120. A single optical modulator 120 may be employed to process signals for the various lens pairs or groups 93, 97. A light multiplexer may be coupled the optical modulator 120 and optical pathways 114, 116 coupled to each lens group 93, 97. The light multiplexer may enable the optical modulator 120 to be alternatively or simultaneously coupled to the lens group 93 or 97. FIGS. 4A to 4D are partial diagrams of embodiments 130, 160, 140, 150 where a probe systems 50, 60, 10, and 30 is inserted into a liquid located within or between two surfaces 122, 124. The liquid may flow between the surfaces from 132 to 134 or be static. In an embodiment the surfaces 122, 124 may be tissue where a bodily fluid passes or exists between the tissues or surfaces 122, 124 including vascular, digestive, or other luminal body or tissue.

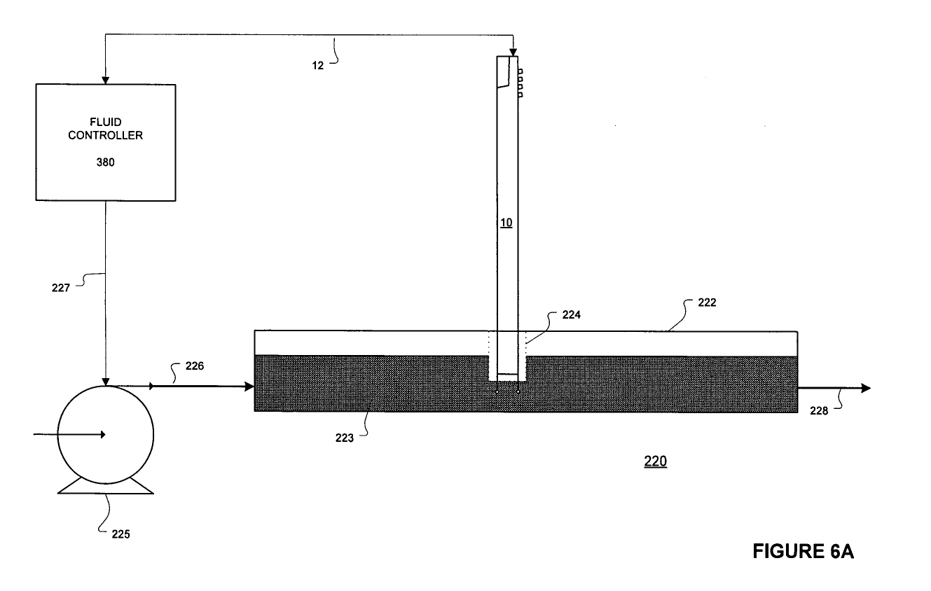

FIGS. 5A to 5D are partial diagrams of embodiments 180, 190, 200, 210 where a probe systems 10, 30, 60, and 40 is inserted into a liquid within a fixed body 172. A liquid 171 having one or more determinable characteristics may be placed in a fixed container 172 such a test tube or other container having desired shape and material specifications. Then one or more signals may be applied to a probe 10, 30, 60, 40, 50 via one or more electrically or optically conductive wires 12, 86, 88, 46A, 46B, 56A, 56B for the embodiments 130, 140, 150, 160, 180, 190, 200, 210 shown in FIGS. 4A to 4D and 5A to 5D.

The invention may monitor the signal(s) as applied to the probes systems 10, 30, 40, 50, and 60. For an electrical signal the invention may monitor the characteristics of the electrical signal and determine characteristics of liquid that is near or adjacent the respective probe system as a function of the monitored electrical signal characteristics. The electrical signal characteristics may include amplitude, phase, impedance, capacitance, and inductance over time or frequency. For an optical signal the invention may monitor the characteristics of the optical signal and determine liquid characteristics as a function of the monitored optical signal characteristics. The optical signal characteristics may include amplitude and phase over time or frequency. A probe system of the invention may be able to generate and receive an electrical or an optical signal simultaneously or alternatively.

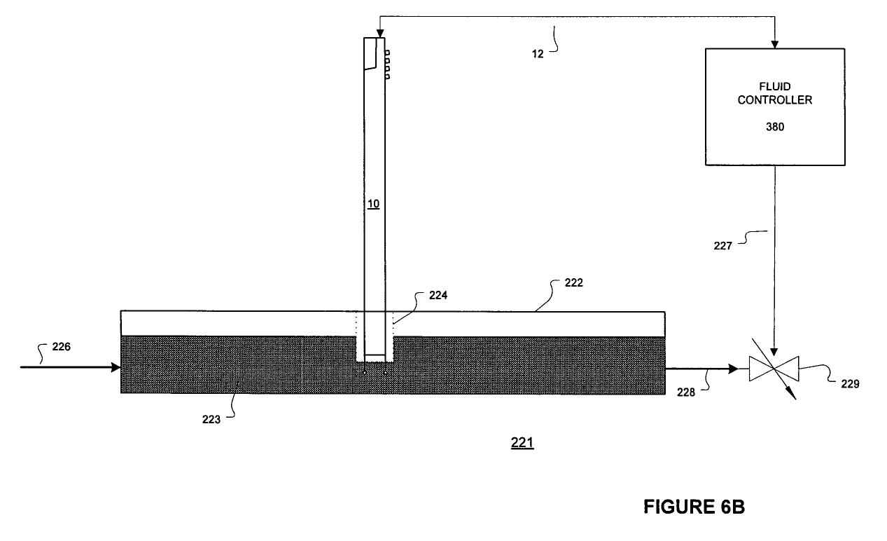

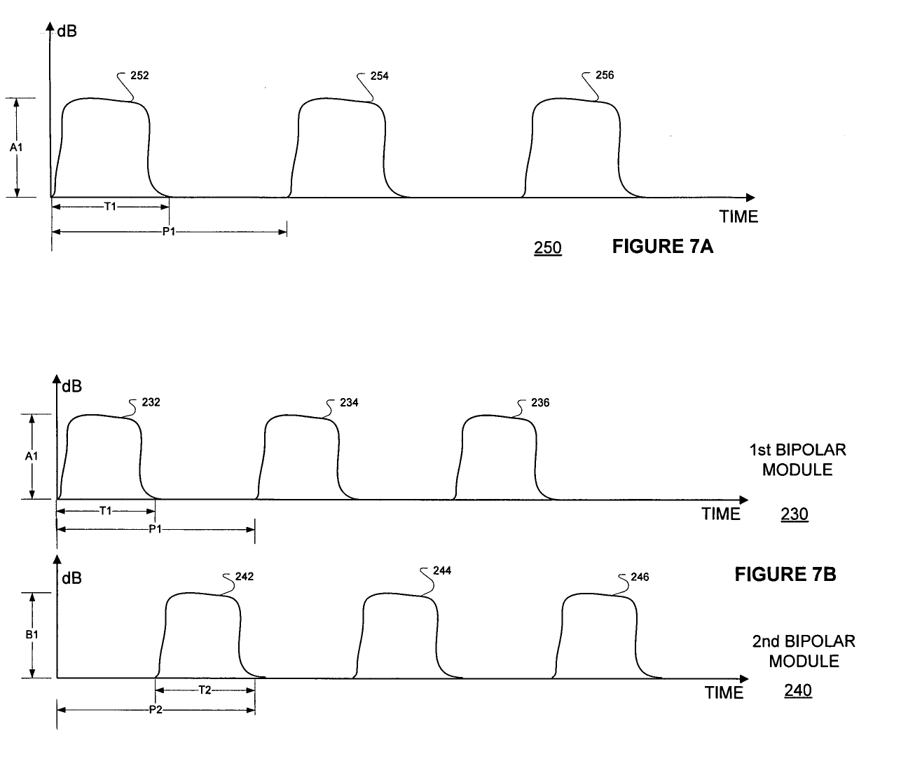

FIGS. 6A and 6B are diagram of flow control architecture that includes at least one liquid probe system 10. In FIG. 6A, flow control architecture 220 includes a liquid probe system 10, fluid controller 380, controllable pump 225, and at a segment of a cannulated tube, pipe, or vessel 222. The cannulated tube, pipe, or vessel 222 may have static or flowing liquid whose flow rate from 226 to 228 may be controlled in part by a liquid pump 225. The fluid controller 380 may be operatively coupled to the liquid probe system 10 via one or more wires 12 and the controllable liquid pump 225 via one or more conductive elements 227. The fluid controller 380 may apply a signal to the liquid probe 10 and monitor the resultant signal to determine one or more characteristics of the liquid 223 about the probe 10.

In an embodiment, an opening in the cannulated tube or vessel 224 may provide a pathway for the probe 10 to physically contact liquid 223. Based on the applied and monitored signal(s), the fluid controller may determine one or more characteristics of the liquid including flow rate, cellular density, cellular or liquid identification, and cellular or molecular transfer pass the probe 1O. The fluid controller 380 may modulate the operation of the pump 225 as a function of one or more determined liquid characteristics. In an embodiment, architecture 220 may be employed to control delivery of pharmacological agents to a mammal where the architecture may be precisely control the molecules of an agent delivered to a patient.

In FIG. 6B, flow control architecture 221 includes a liquid probe system 10, fluid controller 380, controllable valve 229, and at a segment of a cannulated tube, pipe, or vessel 222. The cannulated tube, pipe, or vessel 222 may have static or flowing liquid whose flow rate from 226 to 228 may be controlled in part by the controllable valve 229. The fluid controller 380 may be operatively coupled to the liquid probe system 10 via one or more wires 12 and the controllable valve 229 via one or more conductive elements 227. The fluid controller 380 may apply a signal to the liquid probe 10 and monitor the resultant signal to determine one or more characteristics of the liquid 223 about the probe 10.

In an embodiment, an opening in the cannulated tube or vessel 224 may provide a pathway for the probe 10 to physically contact liquid 223. Based on the applied and monitored signal(s), the fluid controller may determine one or more characteristics of the liquid including flow rate, cellular density, cellular or liquid identification, and cellular or molecular transfer pass the probe 10. The fluid controller 380 may modulate the operation of the valve 229 as a function of one or more determined liquid characteristics. In an embodiment, architecture 221 may be employed to control delivery of pharmacological agents to a mammal where the architecture may be precisely control the molecules of an agent delivered to a patient. In another embodiment the fluid controller 380 may control the operation of one or more pumps 225 and one or more valves 229 where a pump 225 or valve 229 may be part of a intravenous pump system.

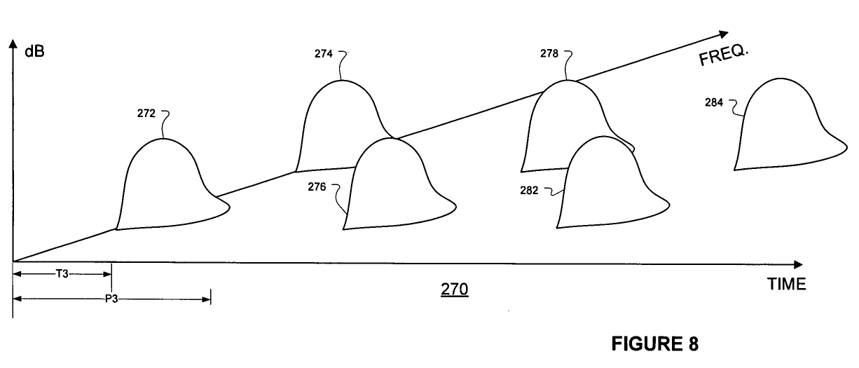

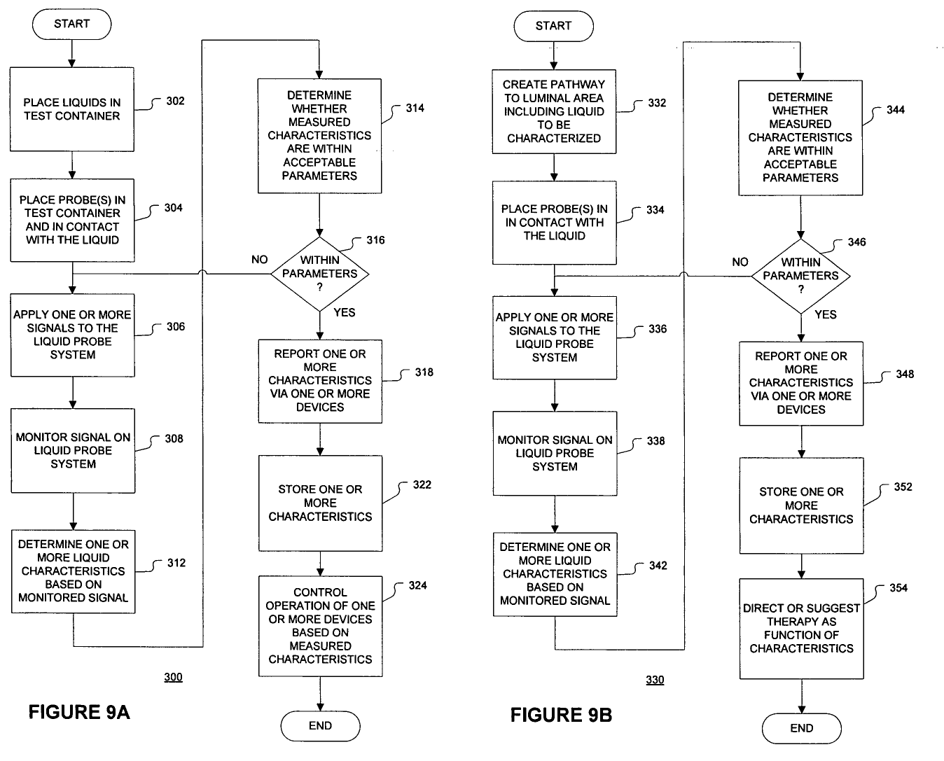

In an embodiment the invention may employ the algorithm 300 shown in FIG. 9A to process or analyze one or more liquids. A user or equipment may place one or more liquids to be analyzed in a container (activity 302). The container may be any container capable of holding a liquid and enabling one or more liquid probe systems 10, 30, 40, 50, or 60 to be placed in contact with the liquid (activity 304). Then one or more signals such as shown in FIGS. 7A, 7B, and 8 may be applied to one or more electrodes or bipolar modules of a probe system (activity 306). The algorithm 300 may monitor the signal on one or more electrodes or bipolar modules of the probe system (activity 308). The algorithm 300 may also monitor remote electrodes systematically coupled to the liquid. Based on the monitored signals, one or more liquid characteristics may be determined (activity 312).

The measured liquid characteristics may include any measurable or determinable characteristic including density, cellular saturation, cellular identification, temperature, and specific gravity. The algorithm 300 may also determine whether the measured or determined liquid characteristics are within predetermined limits, such as physical limits (activity 314). If one or more characteristic is not within predetermined limits (activity 316), the signals or another signal may be applied to the liquid via one or more liquid probes (activity 306). When the measured characteristics are within predetermined limits, the algorithm 300 may report one or more characteristics via one or more devices (activity 318). In an embodiment the algorithm may report one or more characteristics to one ore more devices as a function of the determined characteristics.

The algorithm 300 may also store one more determined characteristics in an violate or non-violate memory (activity 322). The algorithm 300 may use the stored values to set or modify the predetermined limits or determine whether to report measured characteristics to one or more devices. In addition, the algorithm 300 may control the operation of one or more devices based on the measured characteristics (activity 324). The devices may include treatment devices coupled to a patient where the operation or parameters of the treatment devices may be automatically modified as a function of the measured characteristics.

In another embodiment the invention may employ the algorithm 330 shown in FIG. 9B to process or analyze one or more liquids located in a luminal area of a mammal or a luminal area of liquid processing equipment, e.g., the lumen of a native and natural pathway for biological fluids in a body including urethra, fluid ducts or vessels where the fluid or liquid may be in a natural or artificially induced state of flow. A user or equipment may create a pathway to a luminal area including liquid to be tested or characterized (activity 332) or a pathway that is part of a liquid processing equipment. In an embodiment the pathway may be created via a minimally invasive device or cannulated device. In an embodiment the pathway generation device may include a liquid probe. One or more liquid probe systems 10, 30, 40, 50, or 60 to be placed in contact with the liquid via the created pathway (activity 334). Then one or more signals such as shown in FIGS. 7A, 7B, and 8 may be applied to one or more electrodes or bipolar modules of a probe system (activity 336). The algorithm 330 may monitor the signal on one or more electrodes or bipolar modules of the probe system (activity 338). The algorithm 330 may also monitor remote electrodes systematically coupled to the liquid. Based on the monitored signals, one or more liquid characteristics may be determined (activity 342).

The measured liquid characteristics may include any measurable or determinable characteristic including density, cellular saturation, cellular identification, temperature, gaseous saturation, and specific gravity. The algorithm 330 may also determine whether the measured or determined liquid characteristics are within predetermined limits, such as physical limits (activity 344). If one or more characteristic is not within predetermined limits (activity 346), the signals or another signal may be applied to the liquid via one or more liquid probes (activity 336). When the measured characteristics are within predetermined limits, the algorithm 330 may report one or more characteristics via one or more devices (activity 348). In an embodiment the algorithm may report one or more characteristics to one or more devices as a function of the characteristics, e.g., to a medical professional.

The algorithm 330 may also store one more characteristics in a violate or a non-violate memory (activity 352). The algorithm 330 may use the stored values to set or modify the predetermined limits or determine whether to report measured characteristics to one or more devices. In addition, the algorithm 330 may control the operation of one or more devices based on the measured characteristics (activity 354). The devices may include treatment devices coupled to a patient where the operation or parameters of the treatment devices may be automatically modified as a function of the measured characteristics.

As shown in FIG. 8 an electrical or optical signal to be applied to a liquid may include a frequency variable current and voltage that may be applied to the liquid sample at various or pre-determined frequencies. Where the liquid is a bodily fluid, the liquid may be blood, breast milk, urine or saliva, plasma, semen, vaginal fluids, lymph, transudate, exudates, bone marrow, cerebrospinal fluid, interstitial fluid, apheresis fluid, ascites, purulent material and wound secretions.

In an embodiment the monitored response to a signal applied to a liquid probe system may be measured as the signal has passed through a liquid or fluid and then back to the probe via one or more electrodes or bipolar module(s). The applied signal may also pass around or adjacent to the liquid and then to the probe. As the signal is applied to a probe it may be impacted by the liquid in such a way as to modify the signals' voltage and current. In an embodiment, the liquid may temporarily retain some of the energy that was applied to the liquid. Accordingly such energy retention may produce an “out of phase” voltage with respect to current that can be measured in degrees out of phase, which is representative of the liquid's effective capacitance.

In liquids, its effective capacitance may be affected by several factors including the presence of various biological cells in the liquid. Biological cells commonly have an intracellular fluid that is comprised of various electrically active and conductive substances, i.e. Na⁺=10 mM, K⁺=140 mM, Mg⁺⁺=58 mM, HCO₃⁻=10 mM,SO₄⁻=2 mM (approx. 300 mOsm). Such cells have a membrane comprised of a bi-layer phospholipid that is electrically insulative and the surrounding extracellular fluid in most bodily fluids is commonly conductive, i.e. mammalian blood contains: Na⁺=142 mM, K⁺=5 mM, Mg⁺⁺=3 mM, HCO₃⁻=28 mM, SO₄=1 mM (approx. 300 mOsm). Therefore in biological fluids or liquids having cells, a “conductor”-“insulator”-“conductor” arrangement may be present that is analogous to an electrical capacitor where an electrical capacitor is capable of storing energy for a time period of time.

The shape, size, dielectric value, and number of layers of conductors and insulators may affect the magnitude of the capacitor's ability to store energy. The shape, size, biological state, and density of the cells within a volume of fluid or liquid may also affect its capacitance measurement and its ability to absorb or reflect light energy at various frequencies. It is noted that when blood, for example is comprised of either more or less than the normal red blood cell (RBC) count, (usually between 45-50% by volume of cells to liquid in blood), its effective capacitance may vary. Further when the blood volume is lower than normal (due to an internal body subsystem failure such as renal failure, or environmental factors such as heat, physical exertion and lack of fluids intake, or pharmacological interaction), the amount of RBC per unit volume of blood may increase. This could be identified as such by a change in measurement of the voltage-current phase angle or capacitance measurement and lead to a differential diagnosis.

For example, when presumably normal blood is analyzed via the present invention an increase in the phase angle measurement could be correlated to an increase in the white blood cell count of the blood (change in a measurable characteristic of the liquid). In it noted that in a healthy mammalian, the blood's WBC concentration may be 1/500 of the concentration of RBC. During infection the WBC concentration in blood may range from 1/50- 1/10 versus the RBC concentration (predetermined range of measurable characteristics) where the measurement of the increase in WBC may be determined by the present invention. WBC's can include those originating from various parts of the body including the bone marrow, lymph glands and tissue, and the spleen.

WBC may include neutrophils, eosinophils, basophils, platelets, lymphocytes and monocytes in a mammalian. In response to a microbial invader or pathogen, however the WBC count may rise dramatically and may affect the measured capacitance of the blood. The capacitance measurement may be more robustly determined in bodily liquids where the RBC concentration is not dominate such as saliva, plasma, interstitial fluid, urine, feces, semen, vaginal fluids, milk, purulent materials and cerebral spinal fluid. In these circumstances, WBC infiltration as part of the immune system response may comprise a larger percentage of biological cells in the fluid or liquid. The WBC concentration may be measurable as a function of the liquid capacitance that is greater in unhealthy fluid or liquid versus healthy biological fluids. Accordingly a liquid capacitance measurement or characteristic may provide an indication of a systemic infection or a local infection depending on the type of bodily fluid measured, i.e., an increase in effective capacitance of urine (liquid state) could be differentially indicative of an urinary tract, a bladder infection, or a kidney infection. An increase in the effective capacitance in mammary liquid could be indicative of a mammary gland infection. Similarly, in sperm, an effective capacitance increase could be indicative of a reproductive tract infection including the testicles or prostate.

Further, when an infection (bacterial, viral or fungal) is present in a particular localized body part or organ, there may be an increase in the infected organ or tissues cell count in an associated bodily fluid. The cell count increase may be caused by cells damaged by the pathogens where the damaged cells may be subsequently sloughed off into corresponding bodily fluid. The present of the increased cell count in the related, associated, or corresponding fluid may increase the measurable capacitance of the fluid. For example, when proteins are released in the urine via the kidneys or even cells, e.g. kidney, blood cells or endothelial cells, the protein concentration or cellular concentration may be measurable as a change in nominal capacitance of the corresponding fluid or liquid. Further, a change in the ionic concentration in the urine may change the urine capacitance and provide an indication of same.

In accordance with the present invention, a response to the applied signal may be measured or monitored as the signal passes through fluid disposed at, around, or adjacent to a liquid probe system module. It is noted that different cells and ions in fluid or liquid may have different effective capacitance. Accordingly, by measuring or monitoring the electrical characteristics of the response signal the invention or an algorithm 300, 330 may be able to determine the relative concentration of specific cell types and ion concentration within a particular biological bodily fluid through which an applied signal is passed. The cellular concentration and ionic concentration may be determined as a function of stored values of nominal cellular and ionic concentration (and their related measurable characteristics including capacitance) to the currently measured liquid characteristics.

It is noted that a cellular or ionic capacitance may vary as a function of the applied signal characteristics including frequency components. In particular the measurable characteristics may vary as a function of fluid type, cell type, ions, and their respective concentration in the fluid or liquid. In an embodiment the applied electrical signal may be have an increasing frequency component ranging from radio frequency (megahertz) to microwave frequency (gigahertz). Such a frequency spread in the applied signal may enable cell identification where the cell's measurable characteristics vary as a function of the applied signal frequency.

In a preferred method, a probe module may be placed into a static liquid such as shown in FIGS. 5A to 5D or FIGS. 4A to 4D, FIG. 6A, and FIG. 6B (when static) or in a other static liquid such as saliva in the mouth of a patient. The probe module may also be placed in a flowing sample or liquid such as shown in FIGS. 4A to 4D, FIG. 6A, and FIG. 6B (when flowing) or in a moving biological liquid such as a urine stream. It is noted the electrode spacing in the probe modules may be configured as a function of an organism to be characterized, i.e., spaced far enough apart to measure the capacitance changes of cells within the geometry of the module electrode(s). The applied signal may have a low energy level where its subsequent measurement may be compared with similar fluids and known concentrations of cells contained from a previously developed database or storage and a historical moving average of the particular patient's bodily fluid response.

In a configuration of the present invention, a probe module may be mono-polar or bi-polar. In a mono-polar configuration, a single electrode may be disposed on a probe module or a single electrode of a bipolar pair may be energized. A second electrode (effective anode) may be positioned some distance away from the first electrode and within the bodily fluid or in body tissue that is systematically in contact with the liquid to be characterized. It is noted that the probes may be placed within the bodily fluid inside the body either temporarily or chronically in an implanted state.

In an aspect of the present invention, the measurement of the response of bodily fluids to the applied electrical signal, particularly the effective capacitance may be to determine the relative concentration of cells within the fluid where such concentration determination may indicative of the 1) relative health of an individual, 2) state of anemia, 3) state of hydration, 4) organ specific failure, 5) systemic infection, and 6) localized infection. As noted measured characteristics may be stored to provide nominal values or a histogram of the values to assist in the evaluation of a liquid or the pathology of a bodily fluid.

FIG. 7A-7B are diagrams of electrical signal waveforms 230, 240, 250 that may be applied to one or more bipolar modules or groups or optical modules according to various embodiments. The signal waveform 250 includes several square-wave pulses 252, 254, 256 that may be applied to a bipolar module. Each pulse 252, 254, 256 may a have a similar magnitude and envelope. The waveform 250 may be used to energize a bipolar module periodically P1 for a predetermined interval T1 where each pulse 252, 254, 256 has a amplitude A1. In an embodiment, A1 may be about 0.1 milliamperes (mA) to 10 mA, the pulse width T1 may be about 100 microsecond (μs) to 500 μs and the period P1 may from 100 ms to 500 ms as a function of the energy required to create capacitance in a liquid. In another embodiment, A1 may be about 0.5 milliamperes (mA) to 5 mA, the pulse width T1 may be about 200 microsecond (μs) and the period P1 may about 250 ms as a function of the energy to create capacitance in a liquid.

In FIG. 7B a signal waveform 230 may be applied to a first bipolar module or group and a second waveform 240 may be applied or used to energize a second bipolar module. The signal waveform 230 includes several square-wave pulses 232, 234, and 236 and the signal waveform 240 includes several square-wave pulses 242, 244, and 246. Each pulse 232, 234, 236, 242, 244, 246 may a have a similar magnitude and envelope. The waveform 230 may be used to energize a first bipolar module periodically P1 for a predetermined interval T1 where each pulse 232, 234, 236 has an amplitude A1. The waveform 240 may be used to energize a second bipolar module periodically P2 for a predetermined interval T2 where each pulse 242, 244, 246 has an amplitude B1. The pulse width T1, T2 may be about 100 microsecond (μs) to 500 μs and the period P1, P2 may from 100 ms to 500 ms as a function of the energy to create capacitance in a liquid. In another embodiment, A1, A2 may be about 0.5 milliamperes (mA) to 5 mA, the pulse width T1, T2 may be about 200 microsecond (μs) and the period P1, P2 may about 250 ms as a function of the energy required to create capacitance in a liquid. In an embodiment the pulses 232, 234, 236 do not substantially overlap the pulses 242, 244, 246. In an embodiment T1>T2 and P2 is an integer multiple of P1.

FIG. 8 depicts a waveform 270 that includes multiple pulses 272, 274, 276, 278, 282, and 284 that may not overlap in the time or the frequency domain. In an embodiment each pulse 272, 274, 276, 278, 282, and 284 may have a pulse width T3, and frequency spectrum width F1 and period P3. The pulse 272 is frequency offset from the pulse 274, the pulse 276 is frequency offset from the pulse 278, and the pulse 282 is frequency offset from the pulse 284. The pulses 272, 274, 276, 278, 282, and 284 may be applied to a bipolar or optical module to generate a detectable effect on nearby liquid. Pulses 272, 274 having different frequency spectrums may enable the characterization of liquids where the liquids have different electrical or optical properties. In an embodiment the pulses 272, 276, 282 may be applied to a first bipolar or optical module and the pulses 274, 278, 284 may be applied to a second bipolar or optical module. The frequency separation between the respective pulses may enable simultaneous energization of a first and a second bipolar or optical module and subsequent and independent characterization of liquids where the liquids are near or adjacent to the first and the second bipolar or optical modules.

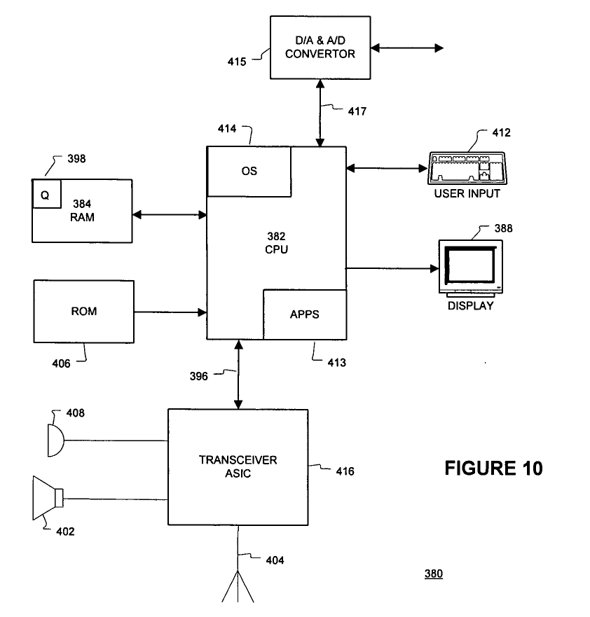

FIG. 10 is a block diagram of an article 380 according to various embodiments. The article 380 shown in FIG. 10 may be used in various embodiments as a part of a probe system 10, 30, 40, 50, 60, 220, 221 where the article 380 may be any computing device including a personal data assistant, cellular telephone, laptop computer, or desktop computer. The article 380 may include a central processing unit (CPU) 382, a random access memory (RAM) 384, a read only memory (ROM”) 406, a display 388, a user input device 412, a transceiver application specific integrated circuit (ASIC) 416, a digital to analog (D/A) and analog to digital (A/D) convertor 415, a microphone 408, a speaker 402, and an antenna 404. The CPU 382 may include an OS module 414 and an application module 413. The RAM 384 may include a queue 398 where the queue 398 may store signal levels to be applied to or monitored on one or more bipolar modules. The OS module 414 and the application module 413 may be separate elements. The OS module 414 may execute a computer system or controller OS. The application module 412 may execute the applications related to the control of a system 10, 30, 40, 50, 60, 220, 221.

The ROM 406 is coupled to the CPU 382 and may store the program instructions to be executed by the CPU 382, OS module 414, and application module 413. The RAM 384 is coupled to the CPU 382 and may store temporary program data, overhead information, and the queues 398. The user input device 412 may comprise an input device such as a keypad, touch pad screen, track ball or other similar input device that allows the user to navigate through menus in order to operate the article 380. The display 388 may be an output device such as a CRT, LCD, LED or other lighting apparatus that enables the user to read, view, or hear user detectable signals.

The microphone 408 and speaker 402 may be incorporated into the device 380. The microphone 408 and speaker 402 may also be separated from the device 380. Received data may be transmitted to the CPU 382 via a bus 396 where the data may include signals for a bipolar module or optical module. The transceiver ASIC 416 may include an instruction set necessary to communicate data, screens, or signals. The ASIC 416 may be coupled to the antenna 404 to communicate wireless messages, pages, and signal information within the signal. When a message is received by the transceiver ASIC 416, its corresponding data may be transferred to the CPU 382 via the serial bus 396. The data can include wireless protocol, overhead information, and data to be processed by the device 380 in accordance with the methods described herein.

The D/A and A/D convertor 415 may be coupled to one or more bipolar modules and optical modules to generate a signal to be used to energize one of the bipolar modules and optical modules. The D/A and A/D convertor 415 may also be coupled to one devices. Any of the components previously described can be implemented in a number of ways, including embodiments in software. Any of the components previously described can be implemented in a number of ways, including embodiments in software. Thus, the bipolar modules and optical modules may all be characterized as “modules” herein. The modules may include hardware circuitry, single or multi-processor circuits, memory circuits, software program modules and objects, firmware, and combinations thereof, as desired by the architect of the system 10, 30, 50, 60 and as appropriate for particular implementations of various embodiments.

The apparatus and systems of various embodiments may be useful in applications other than a sales architecture configuration. They are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, modems, single or multi-processor modules, single or multiple embedded processors, data switches, and application-specific modules, including multilayer, multi-chip modules. Such apparatus and systems may further be included as sub-components within a variety of electronic systems, such as televisions, cellular telephones, personal computers (e.g., laptop computers, desktop computers, handheld computers, tablet computers, etc.), workstations, radios, video players, audio players (e.g., mp3 players), vehicles, medical devices (e.g., heart monitor, blood pressure monitor, etc.) and others. Some embodiments may include a number of methods.

It may be possible to execute the activities described herein in an order other than the order described. Various activities described with respect to the methods identified herein can be executed in repetitive, serial, or parallel fashion.

A software program may be launched from a computer-readable medium in a computer-based system to execute functions defined in the software program. Various programming languages may be employed to create software programs designed to implement and perform the methods disclosed herein. The programs may be structured in an object-orientated format using an object-oriented language such as Java or C++. Alternatively, the programs may be structured in a procedure-orientated format using a procedural language, such as assembly or C. The software components may communicate using a number of mechanisms well known to those skilled in the art, such as application program interfaces or inter-process communication techniques, including remote procedure calls. The teachings of various embodiments are not limited to any particular programming language or environment.

The accompanying drawings that form a part hereof show, by way of illustration and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein individually or collectively by the term “invention” merely for convenience and without intending to voluntarily limit the scope of this application to any single invention or inventive concept, if more than one is in fact disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In the foregoing Detailed Description, various features are grouped together in a single embodiment for the purpose of streamlining the disclosure. This method of disclosure is not to be interpreted to require more features than are expressly recited in each claim. Rather, inventive subject matter may be found in less than all features of a single disclosed embodiment. Thus the following claims are hereby incorporated into the Detailed Description, with each claim standing on its own as a separate embodiment.

What is claimed is:

1. A method of determining a characteristic of a liquid, comprising:
applying an electrical signal to the liquid;
determining the effective capacitance of the liquid as a function of the applied electrical signal; and
determining the liquid characteristic as a function of the applied signal and the determined effective capacitance.

2. The method of claim 1, further comprising:
one of placing an electrode pair in contact with the liquid and placing liquid in contact with an electrode pair; and
applying the electrical signal to the electrode pair.

3. The method of claim 2, further comprising:
monitoring the electrical signal on the electrode pair; and
determining the effective capacitance of the liquid as a function of the monitored electrical signal.

4. The method of claim 1, further comprising:
storing the determined liquid characteristic and the applied signal; and
determining the liquid characteristic as a function of the applied signal, the determined effective capacitance, and one of a stored determined liquid characteristic and a stored applied signal.

5. The method of claim 1, further comprising sending an indication of the determined liquid characteristic to an electronic device.

6. The method of claim 1, further comprising controlling the operation of a device as a function of the determined liquid characteristic.

7. The method of claim 1, wherein the liquid is a mammalian bodily fluid including biological cells.

8. The method of claim 7, comprising:
applying an electrical signal to the bodily fluid;
determining the effective capacitance of the bodily fluid as a function of the applied electrical signal; and
providing an indication of a relative concentration of biological cells in the bodily fluid as a function of the applied signal and the determined effective capacitance.

9. The method of claim 7, comprising:
applying an electrical signal to the bodily fluid;
determining the effective capacitance of the bodily fluid as a function of the applied electrical signal; and
providing an indication of a concentration of first type of biological cells relative to the concentration of another second type of biological cells in the bodily fluid as a function of the applied signal and the determined effective capacitance.

10. The method of claim 7, wherein the mammalian bodily fluid is one of blood, plasma, saliva, urine, semen, vaginal fluids, breast milk, lymph, transudate, exudates, bone marrow, cerebrospinal fluid, interstitial fluid, apheresis fluid, ascites, purulent material, and wound secretions.

10. The method of claim 7, comprising:
applying an electrical signal to body fluid sample of the subject determining the effective capacitance of the bodily fluid as a function of the applied electrical signal;
determining a concentration of a selected biological cell in the bodily fluid as a function of the applied signal and the determined effective capacitance;
comparing the determined biological cell concentration with a reference concentration of a normal biological cell concentration; and
indicating the relative health condition of the bodily fluid as a function the comparison.

11. An apparatus for determining a characteristic of a liquid, comprising:
means for applying an electrical signal to the liquid;
means for determining the effective capacitance of the liquid as a function of the applied electrical signal; and
means for determining the liquid characteristic as a function of the applied signal and the determined effective capacitance.

12. The apparatus of claim 11, further comprising:
a probe having an electrode pair; and
means for applying the electrical signal to the probe electrode pair when the electrode pair is in contact with the liquid.

13. The apparatus of claim 12, further comprising:
means for monitoring the electrical signal on the electrode pair; and
means for determining the effective capacitance of the liquid as a function of the monitored electrical signal.

14. The apparatus of claim 13, further comprising:
means for storing the determined liquid characteristic and the applied signal; and
means for determining the liquid characteristic as a function of the applied signal, the determined effective capacitance, and one of a stored determined liquid characteristic and a stored applied signal.

15. The apparatus of claim 14, further comprising means for sending an indication of the determined liquid characteristic to an electronic device.

16. The apparatus of claim 11, further comprising means for controlling the operation of a device as a function of the determined liquid characteristic.

17. An article of manufacture for use in determining a characteristic of a liquid, the article of manufacture comprising computer readable storage media including program logic embedded therein that causes control circuitry to perform:
applying an electrical signal to the liquid;
determining the effective capacitance of the liquid as a function of the applied electrical signal; and
determining the liquid characteristic as a function of the applied signal and the determined effective capacitance.

18. The article of manufacture of claim 17, further causing control circuitry to perform:
monitoring the electrical signal on the electrode pair; and
determining the effective capacitance of the liquid as a function of the monitored electrical signal.

19. The article of manufacture of claim 17, further causing control circuitry to perform:
storing the determined liquid characteristic and the applied signal; and
determining the liquid characteristic as a function of the applied signal, the determined effective capacitance, and one of a stored determined liquid characteristic and a stored applied signal.

21. The article of manufacture of claim 17, further causing control circuitry to perform sending an indication of the determined liquid characteristic to an electronic device.

22. The article of manufacture of claim 17, further causing control circuitry to perform controlling the operation of a device as a function of the determined liquid characteristic.
